(19) United States
(12) Patent Application Publication
(10) Pub. No.: US 2006/0039512 A1
(43) Pub. Date: Feb. 23, 2006

(54) Large scale integrated circuit for data communication, data communication apparatus, data communication system and data communication method

(75) Inventor: Masaki Yasukawa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC Magnus Communications, Ltd.

(21) Appl. No.: 11/203,213

(22) Filed: Aug. 15, 2005

(30) Foreign Application Priority Data
Aug. 17, 2004 (JP) 2004-237334

(51) Int. Cl. H03K 7/02

(52) U.S. Cl. 375/353

(57) ABSTRACT

A first transmission/reception unit exchanges a pulse amplitude modulation signal having amplitude value is varied at a plurality of levels, using a two-wire telephone cable. An echo canceler extracts only a pulse amplitude modulation signal to be received, and transmitting and receiving equalizers improve the equalization accuracy of the pulse amplitude modulation signals. An error correction circuits correct errors in the pulse amplitude modulation signals, the data quality is improved. Therefore, fast data transmission/reception can be performed by using a two-wire cable instead of a four-wire cable.

This application claims priority prior Japanese patent application JP 2004-237334, the disclosure of which is incorporated herein by reference.

### BACKGROUND OF THE INVENTION

1. Field of the Invention

The present invention relates to a large scale integrated circuit for data communication, a data communication apparatus, a data communication system and a data communication method.

2. Related Background Art

There are a DMT (Discrete Multi Tone) system and a FDM (Frequency Division Multiplexing) system as a system to do data communication with Ethernet (registered trademark).

The DMT system is one of the modulation systems are used in ADSL, which was developed by Amati Communications Corp. and was adopted as the standard by the American National Standards Institute in 1995, and as an advisory opinion by the ITU-T in June, 1999.

The CAP (Carrier-less Amplitude/Phase modulation) system uses a single carrier wave for both the high and low frequency bands. Otherwise DMT system uses a plurality of bands (sub carrier) for both the high and low frequency bands. Each sub carrier has a bandwidth of 4.3 kHz, and QAM (Quadrature Amplitude Modulation) is performed for sub carrier.

The amount of data to be transmitted is eight bits (G.992.2) to fifteen bits (G. 992.1) at the maximum. The reception side collects all of the contents of the individual channels, and as a result, fast communication is enabled (see, for example, “xDSL technique information (on line),” Internet <URL: http://i-vaio. dyndns.org/misc.html> (searched on Aug. 2, 2004) (Reference 1) and “Dictionary Of Communication Network Terms” by Shuwa System Co., Ltd, supervised by Hiromasa Ikeda and edited by Shuwa System Editorial Department, May 5, 2003, p. 139 (Reference 2)).

The FDM system is a Frequency Division Multiplexing technique using different carrier frequencies. The FDM system can transmit a plurality of data sets by a single line simultaneously (see, for example, “Outbreak of Second ADSL War: 8M Super ADSL (on line)” Special Edition, Internet <URL: http://internet.watch.impress.co.jp/www/article/2002/0722/adsl.htm> (searched on Aug. 2, 2004) (Reference 3) and “Dictionary Of Communication Network Terms” by Shuwa System Co., Ltd, supervised by Hiromasa Ikeda and edited by Shuwa System Editorial Department, May 5, 2003, p. 177 (Reference 4)).

For the above described conventional systems, a four-wire cable is required to connect the Ethernet (registered trademark) (e.g., a switching hub) to a router for fast data transmission and reception at 100 Mbit/s.

However, for detached houses and apartment houses, a four-wire cable must be newly laid instead of a telephone line that has previously been laid.

### SUMMARY OF THE INVENTION

Accordingly, an objective of the present invention is to provide a large scale integrated circuit for data communication, a data communication apparatus, a data communication system and a data communication method, for which a telephone line can be utilized.

To achieve the above-mentioned objective, according to a first aspect of the invention, a large scale integrated circuit for Ethernet (registered trademark) data communication comprises:

a first transmission/reception unit for exchanging pulse amplitude modulation signals having amplitude values varied at a plurality of levels, when the transmission/reception unit is connected to a two-wire telephone cable, said pulse amplitude modulation signals being transmitted by the two-wire telephone cable;

an echo canceler for extracting only a pulse amplitude modulation signal that is to be received from the pulse amplitude modulation signals transmitted by the two-wire telephone cable;

a receiving equalizer for improving equalization accuracy of a pulse amplitude modulation signal received;

a transmitting equalizer for improving equalization accuracy of a pulse amplitude modulation signal to be transmitted by the two-wire telephone cable; and

an error correction circuit for correcting an error of a pulse amplitude modulation signal to be transmitted by the two-wire telephone cable.

To achieve the above-mentioned objective, according to a second aspect of the invention, a large scale integrated circuit for Ethernet (registered trademark) data communication comprises:

a first transmission/reception unit for exchanging pulse amplitude modulation signals having amplitude values varied at a plurality of levels, when the transmission/reception unit is connected to a two-wire telephone cable, said pulse amplitude modulation signals being transmitted by the two-wire telephone cable;

an echo canceler for extracting only a pulse amplitude modulation signal that is to be received from the pulse amplitude modulation signals transmitted by the two-wire telephone cable;

a receiving equalizer for improving equalization accuracy of a pulse amplitude modulation signal received;

a transmitting equalizer for improving equalization accuracy of a pulse amplitude modulation signal to be transmitted by the two-wire telephone cable;

an error correction circuit for correcting an error of a pulse amplitude modulation signal to be transmitted by the two-wire telephone cable; and

a second transmission/reception unit for transmitting or receiving data by the four-wire cable, when connected to a four-wire cable.

To achieve the above-mentioned objective, according to a third aspect of the invention, a data communication apparatus for the Ethernet, wherein data communication is performed between one Ethernet communication device and a plurality of communication devices, such as routers, comprising:

a plurality of large scale integrated circuits, each including a first transmission/reception unit for exchanging pulse amplitude modulation signals having amplitude values varied at a plurality of levels, when the transmission/reception unit is connected to a two-wire telephone cable, said pulse amplitude modulation signals being transmitted by the two-wire telephone cable,

an echo canceler for extracting only a pulse amplitude modulation signal that is to be received from the pulse amplitude modulation signals transmitted by the two-wire telephone cable,

a receiving equalizer for improving equalization accuracy of a pulse amplitude modulation signal received,

a transmitting equalizer for improving equalization accuracy of a pulse amplitude modulation signal to be transmitted by the two-wire telephone cable,

an error correction circuit for correcting an error of a pulse amplitude modulation signal to be transmitted by the two-wire telephone cable, and

a second transmission/reception unit for transmitting or receiving data by the four-wire cable, when connected to a four-wire cable; and

a large scale integrated circuit for switching, being selectively connected to one of the large scale integrated circuits for data communication, exchanging data between an external communication device and each of the large scale integrated circuit.

To achieve the above-mentioned objective, according to a fourth aspect of the invention, a data communication system for the Ethernet, wherein data communication is performed between one Ethernet communication device and a plurality of communication devices, such as routers, comprising:

a first data communication apparatus having a plurality of large scale integrated circuits, each having a first transmission/reception unit for exchanging pulse amplitude modulation signals having amplitude values varied at a plurality of levels, when the transmission/reception unit is connected to a two-wire telephone cable, said pulse amplitude modulation signals being transmitted by the two-wire telephone cable,

an echo canceler for extracting only a pulse amplitude modulation signal that is to be received from the pulse amplitude modulation signals transmitted by the two-wire telephone cable,

a receiving equalizer for improving equalization accuracy of a pulse amplitude modulation signal received,

a transmitting equalizer for improving equalization accuracy of a pulse amplitude modulation signal to be transmitted by the two-wire telephone cable,

an error correction circuit for correcting an error of a pulse amplitude modulation signal to be transmitted by the two-wire telephone cable, and

a second transmission/reception unit for, when connected to a four-wire cable, transmitting or receiving data by the four-wire cable, and

a large scale integrated circuit for switching, being selectively connected to one of the large scale integrated circuits for data communication, exchanging data between an external communication device and each of the large scale integrated circuit; and

a second data communication apparatus including a different large scale integrated circuit for data communication, which is connected to the first transmission/reception unit or the second transmission/reception unit of the first data communication apparatus and which has the same structure as said large scale integrated circuit for data communication, and a router connected to the different large scale integrated circuit.

To achieve the above-mentioned objective, according to a fifth aspect of the invention, a data communication method for performing data communication between a first communication device for Ethernet and a plurality of second communication devices such as routers, comprising the steps of:

the first communication device determining whether a bit rate of a signal to be transmitted by a connected cable is 100 Mbps full duplex, 100 Mbps half duplex, 10 Mbps full duplex, 10 Mbps half duplex, or 100 Mbps transmitting by a telephone line;

the first communication device exchanging a signal in accordance with the determination results;

the second communication device determining whether the bit rate of a signal to be transmitted by the connected cable is 100 Mbps full duplex, 100 Mbps half duplex, 10 Mbps full duplex, 10 Mbps half duplex, or 100 Mbps transmitting by a telephone line; and

the second communication device exchanging a signal in accordance with the determination results.

According to the present invention, the first transmission/reception unit exchange pulse amplitude modulation signals having amplitude values varied at a plurality of levels. Pulse amplitude modulation signals are transmitted by the two-wire telephone cable. And since pulse amplitude modulation signals has a plurality of amplitude values, the amount of data to be transmitted during a unit of time can be increased so as to be greater than the amount of data to be transmitted during a unit of time for the pulse modulation signal.

The echo canceler extracts only a pulse amplitude modulation signal that is to be received from the pulse amplitude modulation signals transmitted by the two-wire telephone cable. And the transmitting and receiving equalizers improve the equalization accuracy of the pulse amplitude modulation signals having a data form that matches the telephone cable type.

Furthermore, since the error correction circuit corrects errors of the pulse amplitude modulation signals transferred by the telephone cable. Fast data transmission and reception can be performed by using a two-wire telephone cable, instead of a four-wire cable.

In addition, the two transmission/reception units are provided, i.e., the first transmission/reception unit is compatible with a two-wire telephone cable, and the second transmission/reception unit is compatible with a four-wire cable. Therefore, fast data communication can be performed by using either the two-wire telephone cable or the four-wire cable.

### BRIEF DESCRIPTION OF THE DRAWINGS

FIG. 1 is a block diagram showing a large scale integrated circuit for data communication according to one embodiment of the present invention;

FIG. 2 is a diagram for explaining an 8PAM system as a data communication method according to the invention;

FIG. 3 is a block diagram showing an example data communication system that employs for data communication the large scale integrated circuit according to the present invention;

FIG. 4 is a diagram showing the transmission of signals between the large scale integrated circuits shown in FIG. 1;

FIG. 5 is a conceptual diagram showing an example wherein the data communication system of the present invention is applied for an apartment houses; and

FIG. 6 is a conceptual diagram showing an example wherein the data communication system of the present invention is applied for a detached house.

### DESCRIPTION OF THE PREFERRED EMBODIMENT

The present invention will now be described with reference to the drawings.

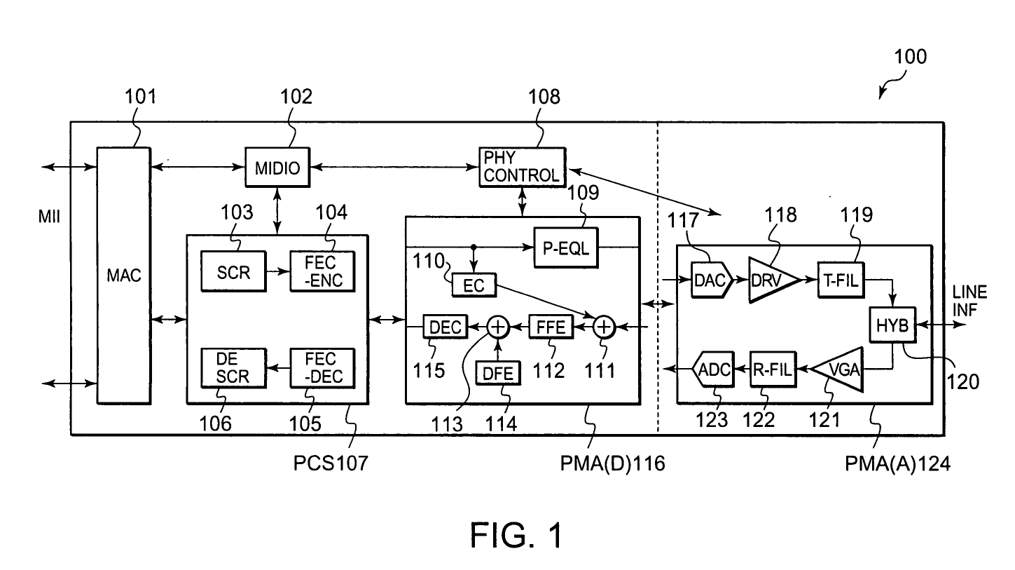

FIG. 1 is a block diagram showing a large integrated circuit for data communication according to one embodiment of the present invention.

In FIG. 1, a large scale integrated circuit 100 for data communication mainly comprises: an interface (MAC) 101, a PCS 107, a PMA(D) 116, a PMA(A) 124 which serves as a first transmission/reception unit, an MIDIO 102 and a PHYCONTROL 108.

The MAC 101 functions as an MAC (Media Access) layer based on the IEEE802.3 Ethernet (registered trademark).

The MIDIO 102 controls and monitors the PCS 107, the PMA(D) 116 and the PMA(A) 124, and also exchanges necessary data with an MII (Media Independent Interface).

The PHYCONTROL 108 controls the PMA(D) 116 and the PMA(A) 124. It should be noted that the parenthetical D refers to the digital signal processing, and the parenthetical A, to the analog signal processing.

The PCS 107 includes a scrambler SCR 103, a transmission error correction circuit FEC-ENC 104, a reception error correction circuit FEC-DEC 105 and a descrambler DESCR 106.

The scrambler SCR 103 equalizes the spectrum of a data signal.

The transmission error correction circuit FEC-ENC 104 corrects an error in data to be transmitted.

The reception error correction circuit FEC-DEC 105 corrects errors in data received.

The descrambler DESCR 106 descrambles the spectrum of a data signal. The PMA(D) 116 includes a transmitting equalizer P-EQL 109, an echo canceler EC 110, adders 111 and 113 and receiving equalizers FFE 112, DFE 114 and DEC 115.

The transmitting equalizer P-EQL 109 improves the equalization accuracy.

The echo canceler EC 110 extracts only a pulse amplitude modulation signal that is to be received from the pulse amplitude modulation signals transmitted by the two-wire telephone cable.

The adder 111 adds a signal transmitted from the preceding stage to a signal transmitted from the echo canceler EC 110.

The adder 113 adds a signal transmitted from the FFE 112 to a signal transmitted from the DFE 114.

The receiving equalizers FFE 112 and DFE 114 improve the equalization accuracy for a transmission path.

The DEC 115 has a function for identifying a received signal that is shaped by the receiving equalizer.

The PMA(A) 124 includes: a digital/analog converter DAC 117, a drive circuit DRV 118, a transmission filter T-FIL 119, a directional coupling circuit HYB 120, a variable gain amplifier VGA 121, a reception filter R-FIL 122 and an analog/digital converter ADC 123.

The digital/analog converter DAC 117 converts a digital signal into an analog signal.

The drive circuit DRV 118 amplifies an input signal.

The transmission filter T-FIL 119 removes an unwanted signal, such as noise, from a signal to be transmitted.

The directional coupling circuit HYB 120 has a function for separating or mixing signals that are to be transmitted or received, and is connected to a telephone line.

The variable gain amplifier VGA 121 adjusts a signal amplitude.

The reception filter R-FIL 122 removes noise from a received signal.

The analog/digital converter ADC 123 converts an analog signal into a digital signal.

The large scale integrated circuit 100 for data communication in FIG. 1 performs fast bi-directional signal transmission at 100 Mbps by using a cable in category 3, which is a two-wire telephone cable, under the following conditions 1) to 9).
1) The 8PAM (Pulse Amplitude Modulation: 8-valued transmission) should be mainly employed (4PAM, 5PAM, 6PAM or 7PAM is also selected, depending on the reception S/N ratio). The symbol rate is about 20 MHz.
2) The echo canceler EC should be provided to suppress echoes that are generated due to the 2W method.
3) The receiving equalizers DFE and FFE should be provided to improve the equalization accuracy for the transmission path.
4) The transmitting equalizer P-EQL should be provided to improve the equalization accuracy.
5) The error correction circuits FEC-ENC and FEC-DEC should be provided.
6) The scrambler SCR and the descrambler DE SCR should be provided to equalize the spectrum of a data signal.
7) A general-purpose MII should be employed as an apparatus side interface (opposite the telephone line side).
8) The directional coupling circuit HYB for separating and mixing signals that are exchanged should be provided for the line input section.
9) The variable gain amplifier VGA for adjusting a signal amplitude should be provided at the first stage of a reception section.

As a result, by using a telephone line which is a pair of lines, the invention system can simultaneously be employed to transmit and receive data signals at 100 Mbps.

The 8PAM system will now be described.

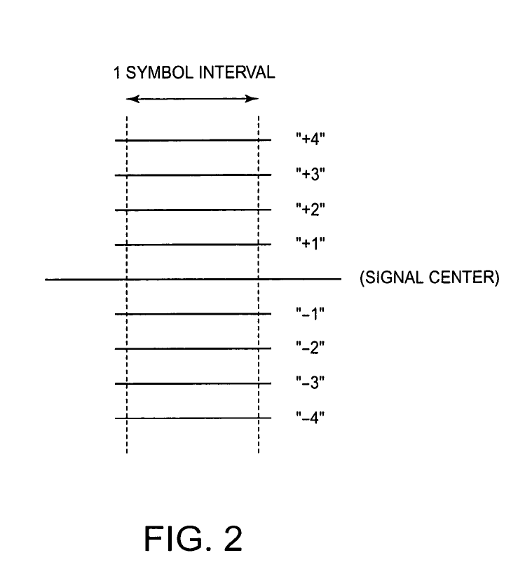

FIG. 2 is a diagram for explaining the 8PAM system as a data communication method according to the invention.

In FIG. 2, four lines are drawn, in both an upper and a lower section, on either side of a signal center line. The length of each horizontal line represents a symbol period, and from the bottom, the individual lines represent amplitude values of “−4”, “−3”, “−2”, “−1”, “+1”, “+2”, “+3” and “+4”. The 8PAM system is a data transmission system that uses these eight amplitude values, “−4” to “+4”.

Instead of the 8PAM system employing the range of amplitude values of from “−4” to “+4”, the 4PAM system may employ a range of from “−2” to “+2”, the 5PAM system may employ a range of from “−2” to “+3”, the 6PAM system may employ a range of from “−3” to “+3” or the 7PAM system man employ a range of from “−3” to “+4”. In this case, it is preferable that the amplitude value be reduced (e.g., from PAM 7 to PAM 6) when the S/N ratio is small, or be increased (e.g., from PAM 4 to PAM 5) when the S/N ratio is high. When the PAM value is nine or greater, the signal bandwidth would be increased, the structure of the apparatus would become complicated and the size of the apparatus is increased. And when the PAM value is seven or smaller, the signal processing can not be appropriately performed. Therefore, the preferable PAM value is eight.

In FIG. 1, the large scale integrated circuit 100 for data communication also includes an identification unit for determining whether the bit rate for a signal to be transmitted by a connected cable is 100 Mbps full duplex, 100 Mbps half duplex, 10 Mbps full duplex, 10 Mbps half duplex, or 100 Mbps by using a telephone line.

Signals are transmitted and received according to the bit rate that is identified, e.g., for full duplex, fast data transmission is performed by using a telephone line at 100 Mbps. As a result, without a new four-wire cable having to be laid, fast data transmission can be performed at 100 Mbps by employing a conventional telephone line.

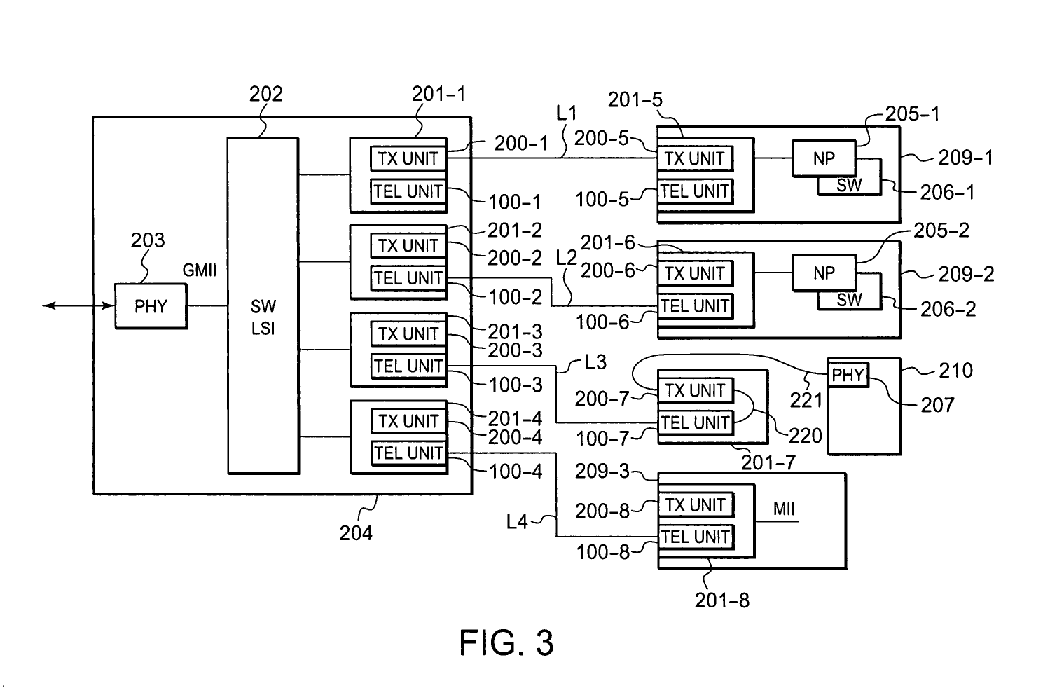

FIG. 3 is a block diagram showing an example data communication system that employs for data communication the large scale integrated circuit according to the present invention.

In the data communication system in FIG. 3, the Ethernet (registered trademark) (e.g., a switching hub) 204, a plurality of routers (three in FIG. 3; however, the number of routers is not limited) 209-1 to 209-3 and a personal computer 210 are connected by a UTP (Universal Terrestrial Pair; an unshielded twisted-pair cable) L1, and telephone lines L2, L3 and L4.

The switching hub 204 includes: a PHY 203, a switching LSI 202 and a plurality of ESU-LSIs (four in FIG. 3; however, the number of ESU-LSIs is not limited) 201-1 to 201-4, which are large scale integrated circuits for data communication. The ESU-LSI 201-1 is an LSI (includes a hybrid IC) comprises a large scale integrated circuit 100-1 for data communication and a well known 100BASE-TX.

The large scale integrated circuit 100-1 includes a first transmission/reception unit that exchanges by using a telephone line, when connected to a two-wire cable, a pulse amplitude modulation signal for which the amplitude value of data is changed at a plurality of levels. The well known 100BASE-TX includes a second transmission/reception unit that transmits or receives data, when connected to a four-wire cable, through the four-wire cable.

Among the Ethernet (registered trademark) specifications for a communication speed of 100 Mbps, for which the specification is defined by the IEEE802.3u task force of the IEEE802.3 working group, the 100BASE-TX employs a Category 5 unshielded twisted-pair cable (UTP) that is standardized by IEEE802.3.

A 100BASE-TX unit (hereinafter referred to as a “TX unit) 200-1, which is the second transmission/reception unit for the ESU-LSI 201-1 of the switching hub 204, is connected to a TX unit 200-5 of the ESU-LSI 201-5 for the router 209-1 by the UTP (L1). Data are transferred by the UTP (L1) at a high rate of 100 Mbps.

A large scale integrated circuit (hereinafter referred to as a “TEL” unit) 100-2, for data communication, for the ESU-LSI 201-2 of the switching hub 204 is connected to a TEL unit 100-6 for the ESU-LSI 201-6 of the router 209-2 by the telephone line L2. The switching hub 204 and the router 209-2 exchange data at a high rate of 100 Mbps by the telephone line L2.

A TEL unit 100-3 for the ESU-LSI 201-3 of the switching hub 204 is connected to a TEL unit 100-7 for the ESU-LSI 201-7 by the telephone line L3, a TEL unit 100-7 and a TX unit 200-7 are connected by a cable 220, and a TX unit 200-7 and the PHY 207 of the personal computer 210 are connected by a cable 221.

In this case, the ESU-LSI 201-7 includes a transmission mode connection unit that exchanges, with an external communication apparatus, the data that is transferred by the four-wire cable.

That is, the data are transferred by using the telephone line L3 at a high rate of 100 Mbps, and are exchanged by the TX unit 200-07 and the personal computer 210. In this case, even when the personal computer 210 can not directly exchange the data at 100 Mbps, the ESU-LSI 201-7 functions as a so-called relay device.

A TEL unit 1004 for the ESU-LSI 201-4 of the switching hub 204 is connected to a TEL unit 100-8 for the ESU-LSI 201-8 of the router 209-3 by the telephone line L4. The switching hub 204 and the router 209-3 exchange data at a high rate of 100 Mbps using the telephone line L4.

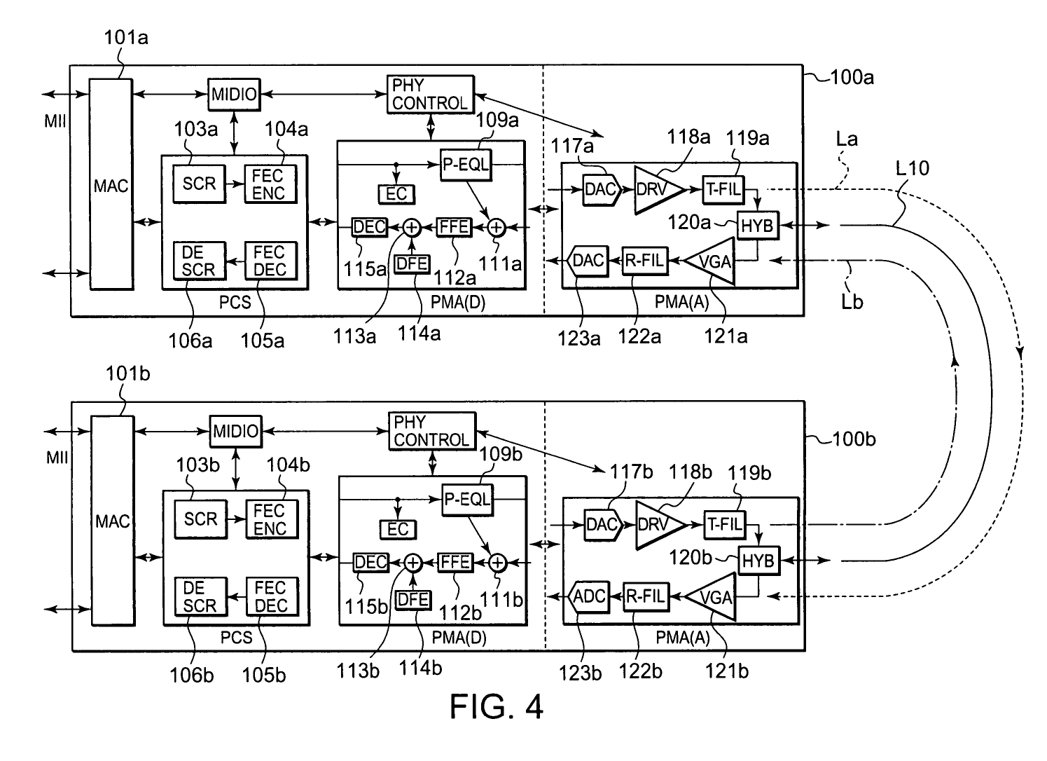

FIG. 4 is a diagram showing the transmission of signals between the large scale integrated circuits shown in FIG. 1.

To simplify the explanation, only the TEL units of the ESU-LSIs are shown in FIG. 4.

A TEL unit 100a (the CO (Central office) side) is connected by a telephone line L10 to another TEL unit 100b (the CPE (Customer Premises Equipment) side), which is on a user side.

Data are transferred from the TEL unit 100a to the TEL unit 100b at a high rate of 100 Mbps by the telephone line L10, in the direction indicated by a broken line La (the downstream direction). At this time, in the TEL unit 100a on the CO side, data are transmitted, in order, from an MAC 101a, a SCR 103a, an FEC-ENC 104a, a P-EQL 109a, a DAC 117a, a DRV 118a, a T-FIL 119a and an HYB 120a. In the TEL unit 100b on the CPE side, data are transmitted, in order, from an HYB 120b, a VGA 121b, an R-FIL 122b, an ADC 123b, an adder 111b, an FFE 112b, an adder 113b, a DEC 115b, an FEC-DEC 105a, a DE-SCR 106b and an MAC 101b.

On the other hand, data are transferred from the TEL unit 100b to the TEL unit 100a at a high rate of 100 Mbps by the telephone line L10, in the direction indicated by a dotted chain line (upstream direction). At this time, in the TEL unit 100b on the CPE side, data are transmitted, in order, from the MAC 101b, an SCR 103b, an FEC-ENC 104b, a P-EQL 109b, a DAC 117b, a DRV 118b, a T-FIL 119b and the HYB 120b. In the TEL unit 100a on the CO side, data are transmitted, in order, from the HYB 120a, a VGA 121a, an R-FIL 122a, an ADC 123a, an adder 111a, an FFE 112a, an adder 113a, a DEC 115a, an FEC-DEC 105a, a DE-SCR 106a and the MAC 101a.

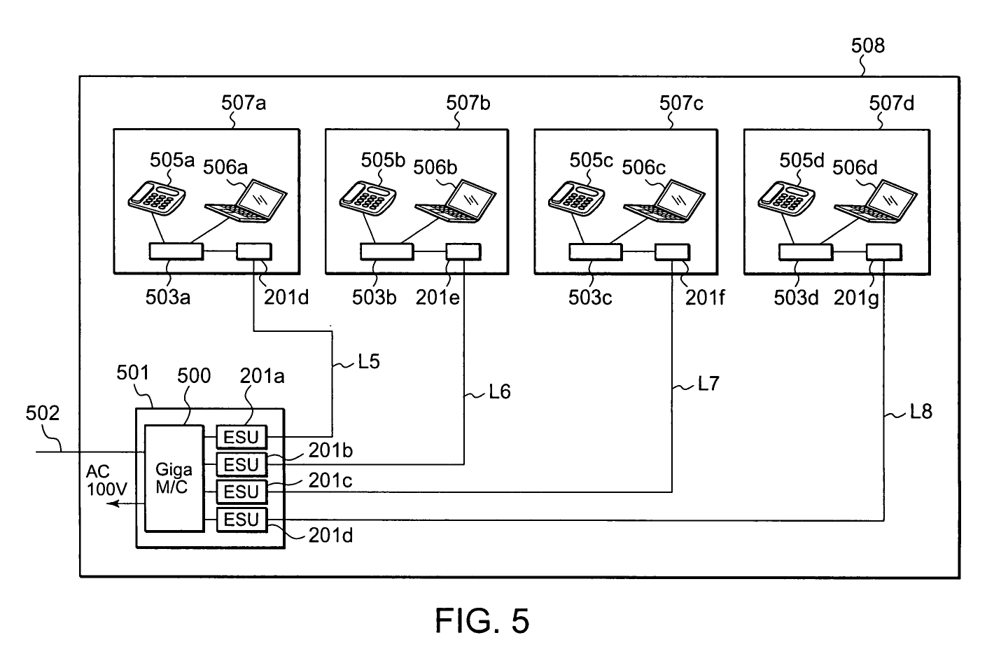

FIG. 5 is a conceptual diagram showing an example wherein the data communication system of the present invention is applied for apartment houses.

Assume that a multi-channel ESU 501, which is a data communication apparatus for the invention, is installed in a switchboard room of an apartment building 508, which is, for example, a multiple-family dwelling. The multi-channel ESU 501 includes: a GigaM/C 500, which is connected to an optical fiber 502 to synthesize or separate signals; and a plurality of ESUs (four in FIG. 5; however, the number of ESUs is not limited) 201a to 201d, which are connected to the GigaM/C 500. The ESUs 201a to 201d correspond to the ESU-LSI 201-1 to 201-4 in FIG. 3.

Telephone lines L5 to L8 are extended from the ESUs 201a to 201d of the multi-channel 501 to individual apartment units 507a to 507d, and are connected to ESUs 201d to 201g provided for the apartment units 507a to 507d. These ESUs 201d to 201g are connected to routers 503a to 503d, which are connected to telephone sets 505a to 505d and to personal computers 506a to 506d.

Also in this case, between the apartment units 507a to 507d and the multi-channel ESU 501, data are exchanged at a high rate of 100 Mbps by using the conventional telephone lines L5 to L8. Therefore, new communication lines (e.g., 100BaseT) need not be laid from the switchboard to the individual apartment units.

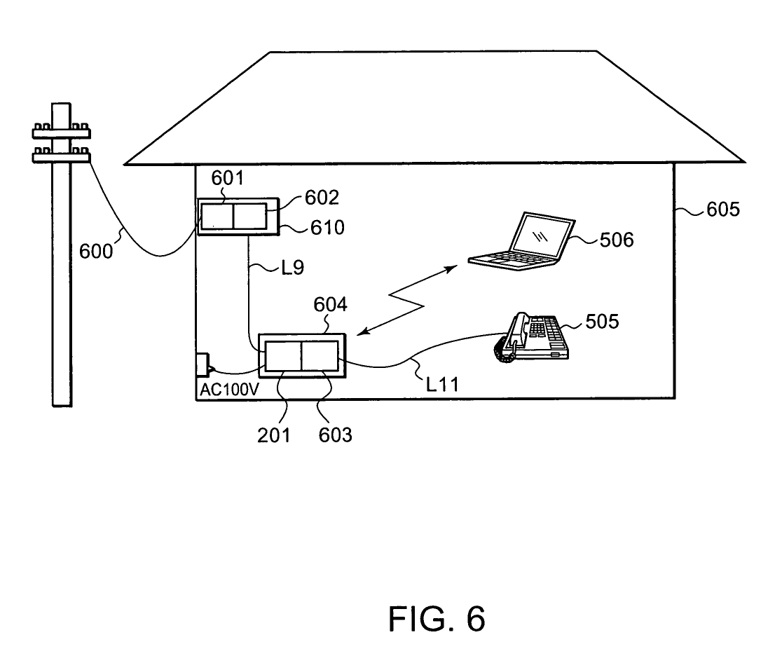

FIG. 6 is a conceptual diagram showing an example wherein the data communication system of the present invention is applied for a detached house.

Assume that a hybrid device 610 connected to an optical fiber 600 is installed in a detached house 605. The hybrid device 610 includes an E/O (photoelectric converter) 601 and an ESU 602, and the ESU is connected by a telephone line L9 to a broadband router 604, which includes an ESU 201 and a wireless/wired router 603. A telephone set 505 is connected to the broadband router 604 by a metal line L11, and a personal computer 506 is wirelessly connected to the broadband router 604.

Also in this case, data are exchanged with the detached house 605 at a high rate of 100 Mbps by the conventional telephone line L9. Therefore, a new communication line (e.g., 100BaseT) need not be laid.

What is claimed is:

1. A large scale integrated circuit for Ethernet data communication comprising:
a first transmission/reception unit for exchanging pulse amplitude modulation signals having amplitude values varied at a plurality of levels, when the transmission/reception unit is connected to a two-wire telephone cable, said pulse amplitude modulation signals being transmitted by the two-wire telephone cable;
an echo canceler for extracting only a pulse amplitude modulation signal that is to be received from the pulse amplitude modulation signals transmitted by the two-wire telephone cable;
a receiving equalizer for improving equalization accuracy of a pulse amplitude modulation signal received;
a transmitting equalizer for improving equalization accuracy of a pulse amplitude modulation signal to be transmitted by the two-wire telephone cable; and
an error correction circuit for correcting an error of a pulse amplitude modulation signal to be transmitted by the two-wire telephone cable.

2. A large scale integrated circuit according to claim 1, further comprising:
an identification unit for determining whether a bit rate of a signal to be transmitted by a connected cable is 100 Mbps full duplex, 100 Mbps half duplex, 10 Mbps full duplex, 10 Mbps half duplex, or 100 Mbps transmitting by a telephone line.

3. A large scale integrated circuit according to claim 1, further comprising:
a scrambler for equalizing a spectrum of the pulse amplitude modulation signal; and
a descrambler for descrambling the spectrum of the pulse amplitude modulation signal.

4. A large scale integrated circuit according to claim 1, wherein the first transmission/reception unit employs an 8PAM system whereby an amplitude value is varied at eight levels.

5. A large scale integrated circuit for Ethernet data communication comprising:
a first transmission/reception unit for exchanging pulse amplitude modulation signals having amplitude values varied at a plurality of levels, when the transmission/reception unit is connected to a two-wire telephone cable, said pulse amplitude modulation signals being transmitted by the two-wire telephone cable;
an echo canceler for extracting only a pulse amplitude modulation signal that is to be received from the pulse amplitude modulation signals transmitted by the two-wire telephone cable;
a receiving equalizer for improving equalization accuracy of a pulse amplitude modulation signal received;
a transmitting equalizer for improving equalization accuracy of a pulse amplitude modulation signal to be transmitted by the two-wire telephone cable;
an error correction circuit for correcting an error of a pulse amplitude modulation signal to be transmitted by the two-wire telephone cable; and
a second transmission/reception unit for transmitting or receiving data by the four-wire cable, when connected to a four-wire cable.

6. A large scale integrated circuit according to claim 5, further comprising:
an identification unit, for determining whether a bit rate of a signal to be transmitted by a connected cable is 100 Mbps full duplex, 100 Mbps half duplex, 10 Mbps full duplex, 10 Mbps half duplex, or 100 Mbps transmitting by a telephone line.

7. A large scale integrated circuit according to claim 5, further comprising:
a scrambler for equalizing a spectrum of the pulse amplitude modulation signal; and
a descrambler for descrambling said spectrum.

8. A large scale integrated circuit according to claim 5, further comprising:
a transmission mode connection unit for connecting the first transmission/reception unit, to which the two-wire telephone cable is connected, and the second transmission/reception unit, to which an external communication unit is connected, so as to transmit to, or receive from, the external communication device data that are transferred by the four-wire cable.

9. A large scale integrated circuit according to claim 5, wherein the first transmission/reception unit employs an 8PAM system whereby an amplitude value is varied at eight levels.

10. A data communication apparatus for the Ethernet, wherein data communication is performed between one Ethernet communication device and a plurality of communication devices, such as routers, comprising:
a plurality of large scale integrated circuits, each including
a first transmission/reception unit for exchanging pulse amplitude modulation signals having amplitude values varied at a plurality of levels, when the transmission/reception unit is connected to a two-wire telephone cable, said pulse amplitude modulation signals being transmitted by the two-wire telephone cable,
an echo canceler for extracting only a pulse amplitude modulation signal that is to be received from the pulse amplitude modulation signals transmitted by the two-wire telephone cable,
a receiving equalizer for improving equalization accuracy of a pulse amplitude modulation signal received,
a transmitting equalizer for improving equalization accuracy of a pulse amplitude modulation signal to be transmitted by the two-wire telephone cable,
an error correction circuit for correcting an error of a pulse amplitude modulation signal to be transmitted by the two-wire telephone cable, and
a second transmission/reception unit for transmitting or receiving data by the four-wire cable, when connected to a four-wire cable; and
a large scale integrated circuit for switching, being selectively connected to one of the large scale integrated circuits for data communication, exchanging data between an external communication device and each of the large scale integrated circuit.

11. A data communication system for the Ethernet, wherein data communication is performed between one Ethernet communication device and a plurality of communication devices, such as routers, comprising:
a first data communication apparatus having
a plurality of large scale integrated circuits, each having
a first transmission/reception unit for exchanging pulse amplitude modulation signals having amplitude values varied at a plurality of levels, when the transmission/reception unit is connected to a two-wire telephone cable, said pulse amplitude modulation signals being transmitted by the two-wire telephone cable,
an echo canceler for extracting only a pulse amplitude modulation signal that is to be received from the pulse amplitude modulation signals transmitted by the two-wire telephone cable,
a receiving equalizer for improving equalization accuracy of a pulse amplitude modulation signal received,
a transmitting equalizer for improving equalization accuracy of a pulse amplitude modulation signal to be transmitted by the two-wire telephone cable,
an error correction circuit for correcting an error of a pulse amplitude modulation signal to be transmitted by the two-wire telephone cable, and
a second transmission/reception unit for, when connected to a four-wire cable, transmitting or receiving data by the four-wire cable, and
a large scale integrated circuit for switching, being selectively connected to one of the large scale integrated circuits for data communication, exchanging data between an external communication device and each of the large scale integrated circuit; and
a second data communication apparatus including
a different large scale integrated circuit for data communication, which is connected to the first transmission/reception unit or the second transmission/reception unit of the first data communication apparatus and which has the same structure as said large scale integrated circuit for data communication, and
a router connected to the different large scale integrated circuit.

12. A large scale integrated circuit according to claim 11, wherein the first transmission/reception unit employs an 8PAM system whereby an amplitude value is varied at eight levels.

13. A data communication method for performing data communication between a first communication device for Ethernet and a plurality of second communication devices such as routers, comprising the steps of:
the first communication device determining whether a bit rate of a signal to be transmitted by a connected cable is 100 Mbps full duplex, 100 Mbps half duplex, 10 Mbps full duplex, 10 Mbps half duplex, or 100 Mbps transmitting by a telephone line;
the first communication device exchanging a signal in accordance with the determination results;
the second communication device determining whether the bit rate of a signal to be transmitted by the connected cable is 100 Mbps full duplex, 100 Mbps half duplex, 10 Mbps full duplex, 10 Mbps half duplex, or 100 Mbps transmitting by a telephone line; and
the second communication device exchanging a signal in accordance with the determination results;

14. A data communication method according to claim 13, wherein an 8PAM system whereby an amplitude value is varied at eight levels is employed for transmission/reception of data.
